(19) United States
(12) Patent Application Publication
(10) Pub. No.: US 2026/0020352 A1
(43) Pub. Date: Jan. 15, 2026

(54) SILICON CARBIDE CONTROLLED RECTIFIER DEVICE FOR ELECTROSTATIC DISCHARGE PROTECTION

(71) Applicant: BOARD OF TRUSTEES OF THE UNIVERSITY OF ARKANSAS, Little Rock (AR)

(72) Inventors: H. Alan Mantooth, Fayetteville (AR); Hui Wang, Fayetteville (AR); Pengyu Lai, Fayetteville (AR); Zhong Chen, Fayetteville (AR)

(73) Assignee: BOARD OF TRUSTEES OF THE UNIVERSITY OF ARKANSAS, Little Rock (AR)

(21) Appl. No.: 19/267,708

(22) Filed: Jul. 14, 2025

Related U.S. Application Data
(60) Provisional application No. 63/670,354, filed on Jul. 12, 2024.

(51) Int. Cl. H10D 89/60; H10D 62/832

(52) U.S. Cl. CPC H10D 89/713; H10D 62/8325

(57) ABSTRACT

A silicon carbide (SiC) controlled rectifier structure for on-chip electrostatic discharge protection of SiC integrated circuits. The SiC controlled rectifier includes a base layer as well as a P-well region and an N-well region positioned above the base layer. The SiC controlled rectifier further includes a doped P+ region and a doped N+ region positioned within the P-well region. The SiC controlled rectifier additionally includes a cathode in electrical communication with the doped P+ region and the doped N+ region of the P-well region. Furthermore, the SiC controlled rectifier includes a doped P+ region and a doped N+ region positioned within the N-well region. Additionally, the SiC controlled rectifier includes an anode in electrical communication with the doped P+ region and the doped N+ region of the N-well region.

### STATEMENT REGARDING FEDERALLY SPONSORED RESEARCH

This invention was made with government support under W911NF1920231 awarded by the Department of Defense. The government has certain rights in the invention.

### TECHNICAL FIELD

The present invention relates generally to silicon carbide devices, and more particularly to a silicon carbide (SiC) controlled rectifier device for electrostatic discharge protection.

### BACKGROUND

With the development of power electronics, aerospace, and automobile industries, there is a growing expectation to employ wide bandgap (WBG) semiconductor devices and integrated circuits (ICs) in high-temperature environments. The design of silicon (Si) based ICs for high-temperature (e.g., 150° C.) applications becomes more challenging due to the drastic alteration of the leakage current, threshold voltage, and electron mobility.

A silicon carbide (SiC) device is an electronic component made from the semiconductor material silicon carbide. These devices offer superior performance compared to traditional silicon-based devices, especially in high-power, high-temperature, and high-frequency applications. SiC devices, such as MOSFETs and Schottky diodes, are widely used in power electronics, including electric vehicles, solar inverters, and industrial motor drives.

A variety of SiC-based ICs have been demonstrated, such as high-current, high-temperature bipolar SiC ICs, SiC digital logic gates functioning at 600° C., SiC CMOS digital circuits operating at temperatures exceeding 300° C., high-temperature (i.e., ˜400° C.) analog ICs in SiC bipolar technology and 4 hexagonal (4H)-SiC ultraviolet (UV) photodiodes. Although these SiC ICs show high performance with a wide range of operating temperatures, such SiC ICs exhibit reliability issues.

Among the reliability issues, electrostatic discharge (ESD) is a great matter of concern that causes more than one-third IC failures. Therefore, in order to improve the reliability of SiC ICs, electrostatic discharge of SiC ICs needs to be addressed.

Unfortunately, an area-efficient, effective electrostatic discharge protection device to improve the reliability of SiC ICs has not yet been developed.

### SUMMARY

In one embodiment of the present disclosure, a silicon carbide (SiC) controlled rectifier comprises a base layer as well as a P-well region and an N-well region positioned above the base layer. The SiC controlled rectifier further comprises a doped P+ region and a doped N+ region positioned within the P-well region. The SiC controlled rectifier additionally comprises a cathode in electrical communication with the doped P+ region and the doped N+ region of the P-well region. Furthermore, the SiC controlled rectifier comprises a doped P+ region and a doped N+ region positioned within the N-well region. Additionally, the SiC controlled rectifier comprises an anode in electrical communication with the doped P+ region and the doped N+ region of the N-well region.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present invention can be obtained when the following detailed description is considered in conjunction with the following drawings, in which:

FIG. 1 illustrates the cross-sectional view of the high voltage (HV) silicon carbide (SIC) controlled rectifier for on-chip electrostatic discharge protection of SiC integrated circuits (ICs) in accordance with an embodiment of the present disclosure;

FIG. 2 illustrates a sample of fabricating the HV SiC controlled rectifier of FIG. 1 using a 4H-SiC bipolar-CMOS-DMOS (BCD) process in accordance with an embodiment of the present disclosure;

FIG. 3 is a graph illustrating the transmission line pulse (TLP) measurement results of the HV SiC controlled rectifier of FIG. 1 with drift lengths of 7 μm and 11 μm in accordance with an embodiment of the present disclosure; and

FIG. 4 is a graph illustrating the TLP measurements results of the HV SiC controlled rectifier of FIG. 1 with a 4 μm gate length, a 7 μm drift length, and varying Vg in accordance with an embodiment of the present disclosure.

### DETAILED DESCRIPTION

As stated above, a silicon carbide (SiC) device is an electronic component made from the semiconductor material silicon carbide. These devices offer superior performance compared to traditional silicon-based devices, especially in high-power, high-temperature, and high-frequency applications. SiC devices, such as MOSFETs and Schottky diodes, are widely used in power electronics, including electric vehicles, solar inverters, and industrial motor drives.

A variety of SiC-based ICs have been demonstrated, such as high-current, high-temperature bipolar SiC ICs, SiC digital logic gates functioning at 600° C., SiC CMOS digital circuits operating at temperatures exceeding 300° C., high-temperature (i.e., ˜400° C.) analog ICs in SiC bipolar technology and 4 hexagonal (4H)-SiC ultraviolet (UV) photodiodes. Although these SiC ICs show high performance with a wide range of operating temperatures, such SiC ICs exhibit reliability issues.

Among the reliability issues, electrostatic discharge (ESD) is a great matter of concern that causes more than one-third IC failures. Therefore, in order to improve the reliability of SiC ICs, electrostatic discharge of SiC ICs needs to be addressed.

Unfortunately, an area-efficient, effective electrostatic discharge protection device to improve the reliability of SiC ICs has not yet been developed.

The embodiments of the present disclosure provide a means for an area-efficient, effective electrostatic discharge protection device to improve the reliability of SiC ICs. In some embodiments, such an electrostatic discharge protection device corresponds to a SiC controlled rectifier structure for on-chip electrostatic discharge protection of SiC ICs. For example, in some embodiments, the electrostatic discharge protection device corresponds to an area-efficient high-voltage (HV) silicon carbide (SiC) controlled rectifier structure based on a 4H-SiC bipolar-CMOS-DMOS (BCD) process for SiC integrated circuits (ICs).

In one embodiment, the area-efficient HV SiC controlled rectifier structure is formed by adding a highly doped P+ region in SiC laterally-diffused metal-oxide semiconductor (LDMOS) devices. In one embodiment, the SiC controlled rectifier structure is fabricated using a 4H-SiC BCD process and is characterized using a 500Ω load transmission line pulse (TLP) system to demonstrate its electrostatic discharge performance. The TLP experimental results show that the SiC controlled rectifier structure triggers at approximately 230 V with a failure current (It2) of around 2 A (i.e., 33 mA/μm).

These and other features will be discussed in greater detail below.

In the following description, numerous specific details are set forth to provide a thorough understanding of the present disclosure. However, it will be apparent to those skilled in the art that the present disclosure may be practiced without such specific details. In other instances, well-known circuits have been shown in block diagram form in order not to obscure the present disclosure in unnecessary detail. For the most part, details considering timing considerations and the like have been omitted inasmuch as such details are not necessary to obtain a complete understanding of the present disclosure and are within the skills of persons of ordinary skill in the relevant art.

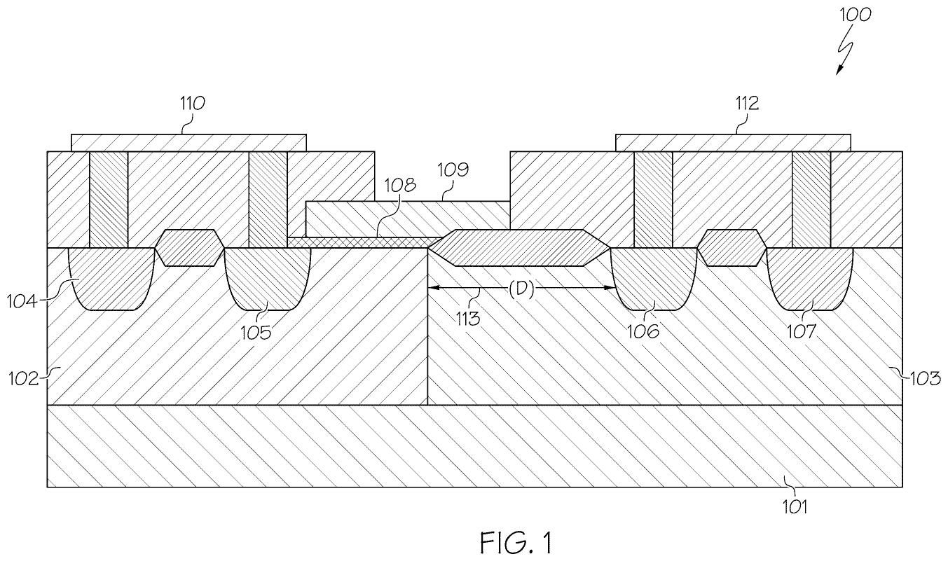

Referring now to the Figures in detail, FIG. 1 illustrates the cross-sectional view of the high voltage (HV) silicon carbide (SiC) controlled rectifier 100 for on-chip electrostatic discharge protection of SiC integrated circuits (ICs) in accordance with an embodiment of the present disclosure. In one embodiment, HV SiC controlled rectifier 100 is based on a bipolar-CMOS-DMOS (BCD) process. In one embodiment, HV SiC controlled rectifier 100 is a component of a semiconductor device. In one embodiment, HV SiC controlled rectifier 100 is a component of a wide bandgap (WBG) semiconductor device. In one embodiment, HV SiC controlled rectifier 100 is a component of an integrated circuit. In one embodiment, an electronic device includes HV SiC controlled rectifier 100, where the electronic device is a semiconductor device, a wide bandgap (WBG) semiconductor device, an integrated circuit (IC), or combinations thereof.

As illustrated in FIG. 1, in one embodiment, HV SiC controlled rectifier 100 includes a base layer 101. In one embodiment, base layer 101 is an epitaxy layer which can be either P-type or N-type. In another alternative embodiment, base layer 101 is a substrate.

Furthermore, as illustrated in FIG. 1, HV SiC controlled rectifier 100 includes region 102 corresponding to a P-well region and includes region 103 corresponding to an N-well region. In one embodiment, regions 102, 103 are located in an epitaxy layer. In one embodiment, such regions 102, 103 are formed by ion implantation.

Additionally, as shown in FIG. 1, P-well region 102 includes region 104, which is a highly doped P+ region, and region 105, which is a highly doped N+ region. Furthermore, N-well region 103 includes region 106, which is a highly doped N+ region and region 107, which is a highly doped P+ region.

Furthermore, as shown in FIG. 1, HV SiC controlled rectifier 100 includes cathode 110, which is in electrical communication with regions 104, 105. Furthermore, in one embodiment, HV SiC controlled rectifier 100 includes anode 112, which is in electrical communication with regions 106, 107.

In one embodiment, as illustrated in FIG. 1, on the top of the P-well and N-well regions 102, 103, there is a gate oxide layer 108, and a gate polysilicon layer (gate) 109, which is on the top of gate oxide layer 108.

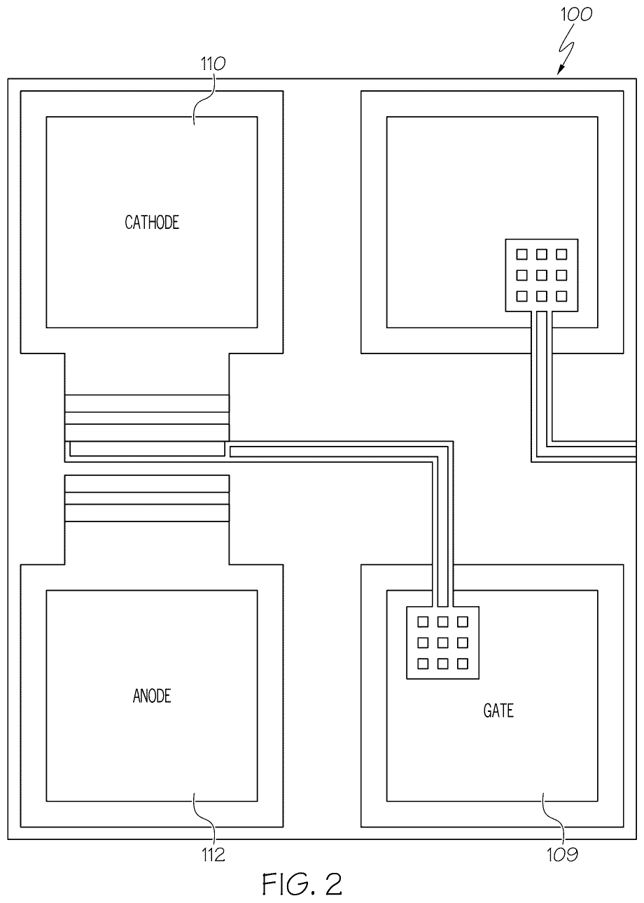

In one embodiment, HV SiC controlled rectifier 100 of FIG. 1 is fabricated using a 4 hexagonal (4H)-SiC bipolar-CMOS-DMOS (BCD) process. FIG. 2 illustrates a sample of fabricating HV SiC controlled rectifier 100 of FIG. 1 using a 4H-SiC BCD process in accordance with an embodiment of the present disclosure.

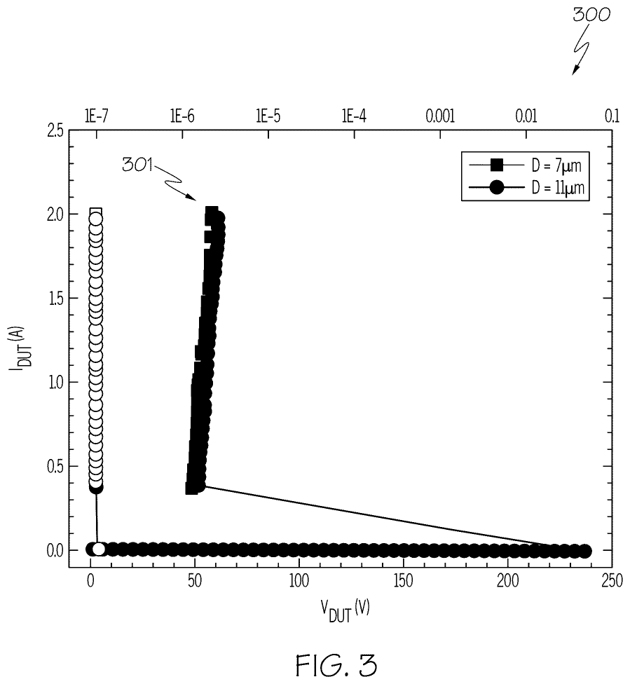

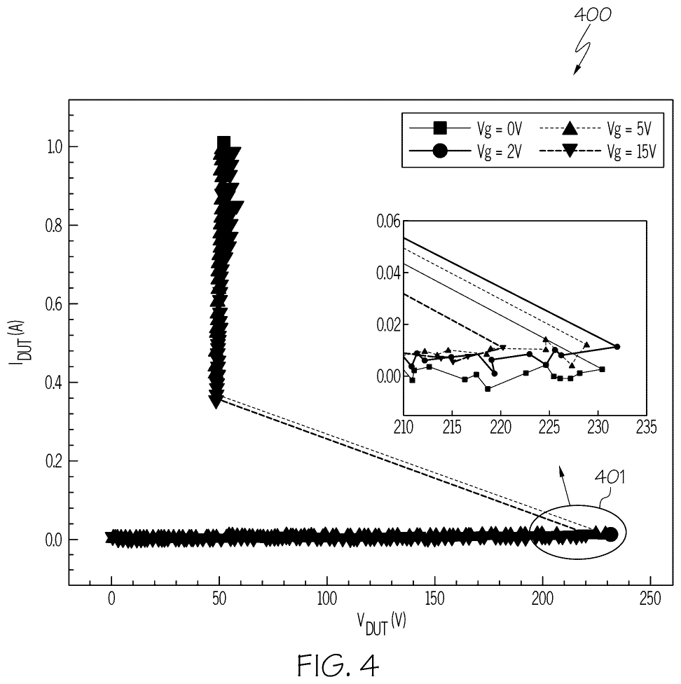

As show in FIG. 2, three bonding pads are connected to the terminals of anode 112, cathode 110 and gate 109 for the convenience of measurements. In one embodiment, SiC controlled rectifier 100 has a gate length of 4 μm and a channel width of 60 μm. Various drift lengths (see 113 in FIG. 1, which is labeled “D”) of HV SiC controlled rectifier structure 100 (e.g., 7 μm and 11 μm) were fabricated to investigate their electrostatic discharge behaviors as discussed further below in connection with FIGS. 3-4. A drift length, as used herein, refers to the distance a charged particle travels in a specific direction due to an electric filed before its motion is randomized by collisions or other scattering events.

The 500Ω impedance transmission line pulse (TLP) measurement results of HV SiC controlled rectifier 100 with varying drift lengths (D) are shown in FIG. 3.

FIG. 3 is a graph 300 illustrating the TLP measurement results of HV SiC controlled rectifier 100 with drift lengths of 7 μm and 11 μm in accordance with an embodiment of the present disclosure.

As shown in FIG. 3, the leakage current (IDUT), where DUT refers to the device under test corresponding to HV SiC controlled rectifier 100, is measured under a 5 V DC bias to monitor the failure points 301 of HV SiC controlled rectifier 100. The trigger voltage (Vt1), holding voltage (Vh) and breakdown current (It2) show little change when the drift length varies from 7 μm to 11 μm. Vt1 is the triggering voltage at which the device starts to conduct and redirects the electrostatic discharge (ESD) current away from sensitive circuitry. Vh is the holding voltage. It2 is the second breakdown current or failure current.

As illustrated in FIG. 3, Vt1 increases from 230 V to 237 V. The Vh of HV SiC controlled rectifier 100 is ˜48 V. The It2 of HV SiC controlled rectifier 100 (i.e., 33 mA/μm) is at the same level when compared with that of the similar Si-based devices (i.e., 10 mA/μm to 50 mA/μm). This indicates that HV SiC controlled rectifier 100 is a high area-efficient ESD protection device.

To further investigate HV SiC controlled rectifier 100, 500 22 transmission line pulse (TLP) measurements with different gate bias (Vg) were carried out. The TLP measurement results of HV SiC controlled rectifier 100 with a 4 μm gate length, a 7 μm drift length, and varying Vg are shown in FIG. 4.

FIG. 4 is a graph 400 illustrating the TLP measurements results of HV SiC controlled rectifier 100 with a 4 μm gate length, a 7 μm drift length, and varying Vg in accordance with an embodiment of the present disclosure.

As illustrated in FIG. 4, Vh shows minor dependence on Vg. Vt1 shows a slight decrease (i.e., from ˜230 V to 220 V) (see 401) when Vg increases from 0 V to 15 V.

The principles of the present disclosure provide an area-efficient high-voltage (HV) silicon carbide (SiC) controlled rectifier for on-chip electrostatic discharge (ESD) protection in SiC integrated circuits (ICs). In one embodiment, the HV SiC controlled rectifier triggers at approximately 220 V, and its failure current is approximately 33 mA/μm.

As previously discussed, SiC ICs are crucial for high-temperature applications in power electronics, aerospace, and automotive industries, but ESD protection remains a challenge. The HV SiC controlled rectifier of the present disclosure, fabricated using a 4H-SiC BCD process, addresses this issue by offering efficient ESD protection, enhancing the reliability of SiC ICs in harsh environments.

One of the problems addressed by the present disclosure is the lack of efficient on-chip electrostatic discharge (ESD) protection for silicon carbide (SiC) integrated circuits (ICs), particularly in high-temperature and harsh environment applications, such as power electronics, aerospace, and automotive industries. Existing SiC-based ICs demonstrate high performance but suffer from reliability issues, with ESD being a significant concern that can lead to IC failures. The present disclosure addressed such a problem by enhancing the reliability of SiC ICs by providing an area-efficient HV SiC controlled rectifier structure specifically designed for on-chip ESD protection.

The benefits include: (1) reliable and robust high temperature chips using SiC integrated circuits; and (2) an area-efficient ESD protection solution for SiC devices. Applications include: (1) SiC devices; (2) SiC integrated circuits; and (3) harsh environment sensors.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A silicon carbide (SiC) controlled rectifier comprising:
a base layer;
a P-well region and an N-well region positioned above said base layer;
a doped P+ region and a doped N+ region positioned within said P-well region;
a cathode in electrical communication with said doped P+ region and said doped N+ region of said P-well region;
a doped P+ region and a doped N+ region positioned within said N-well region; and
an anode in electrical communication with said doped P+ region and said doped N+ region of said N-well region.

2. The silicon carbide (SiC) controlled rectifier as recited in claim 1 further comprising:
a gate oxide layer positioned above said P-well region and said N-well region.

3. The silicon carbide (SiC) controlled rectifier as recited in claim 2 further comprising:
a gate polysilicon layer positioned above said gate oxide layer.

4. The silicon carbide (SiC) controlled rectifier as recited in claim 1, wherein said base layer is an epitaxy layer

5. The silicon carbide (SiC) controlled rectifier as recited in claim 4, wherein said epitaxy layer comprises a P-type epitaxy layer.

6. The silicon carbide (SiC) controlled rectifier as recited in claim 4, wherein said epitaxy layer comprises an N-type epitaxy layer.

7. The silicon carbide (SiC) controlled rectifier as recited in claim 1, wherein said base layer is a substrate.

8. The silicon carbide (SiC) controlled rectifier as recited in claim 1, wherein said P-well region and said N-well region are adjacent to one another.

9. The silicon carbide (SiC) controlled rectifier as recited in claim 1, wherein said silicon carbide (SiC) controlled rectifier is a component of a semiconductor device.

10. The silicon carbide (SiC) controlled rectifier as recited in claim 1, wherein said silicon carbide (SiC) controlled rectifier is a component of a wide bandgap (WBG) semiconductor device.

11. The silicon carbide (SiC) controlled rectifier as recited in claim 1, wherein said silicon carbide (SiC) controlled rectifier is a component of an integrated circuit (IC).

12. The silicon carbide (SIC) controlled rectifier as recited in claim 1, wherein said silicon carbide (SiC) controlled rectifier is made based on a SiC laterally-diffused metal-oxide semiconductor (LDMOS) device.

13. The silicon carbide (SiC) controlled rectifier as recited in claim 1, wherein said silicon carbide (SiC) controlled rectifier is fabricated using a 4 hexagonal (4H)-SiC bipolar-CMOS-DMOS process.

14. The silicon carbide (SiC) controlled rectifier as recited in claim 1, wherein said P-well region and said N-well region are formed by ion implantation.

15. An electronic device, wherein the electronic device comprises said silicon carbide (SiC) controlled rectifier of claim 1.

16. The electronic device as recited in claim 15, wherein said electronic device is selected from the group consisting of: a semiconductor device, a wide bandgap (WBG) semiconductor device, an integrated circuit (IC), or combinations thereof.
